(19) United States
(12) Patent Application Publication
(10) Pub. No.: US 2006/0017079 A1
(43) Pub. Date: Jan. 26, 2006

(54) N-type transistor with antimony-doped ultra shallow source and drain

(76) Inventors: Srinivasan Chakravarthi, Murphy, TX (US); Amitabh Jain, Allen, TX (US); Xin Zhang, Plano, TX (US)

Correspondence Address: TEXAS INSTRUMENTS INCORPORATED, P O BOX 655474, M/S 3999, DALLAS, TX, 75265, US

(21) Appl. No.: 10/896,421

(22) Filed: Jul. 21, 2004

(51) Int. Cl. H01L 29/76; H01L 21/425; H01L 31/117; H01L 21/44

(52) U.S. Cl. 257/288; 438/514; 438/660; 257/616

(57) ABSTRACT

We disclose a process for forming ultra shallow n⁺p junctions. The junction is formed by, for example, implanting 3E14 ions/cm² of antimony ions at 5 keV into silicon. The silicon is pre-amorphized by a previous ion-implantation. The pre-amorphizing implant species may be germanium or arsenic. Germanium may be implanted at 15 keV and Arsenic may be implanted at 2 keV. Both the pre-amorphizing implant and the antimony implant are preferably through bare silicon surface—not covered with any foreign material with the exception of possibly a layer of native oxide. The junction is annealed at about 950° C. following the implants to re-crystallize the implanted region and to activate the implanted ions. The ultra shallow junction is superior because it has a abrupt junction, high sheet resistance and can be formed with low thermal budget.

This invention relates to the field of semiconductor integrated devices, and particularly relates to an improved source and drain of a n-type MOS transistor.

### DESCRIPTION OF THE RELATED ART

P-n junctions are integral parts of integrated circuit (IC) devices. In the early days of IC manufacturing, p-n junctions were formed with a two-step process to incorporate a controlled amount of foreign atoms (dopant) into a crystalline semiconductor material such as germanium or silicon. First, a glassy material containing, for example, phosphorus atoms are deposited at an elevated temperature on the surface of a disk shaped silicon wafer previously doped with boron atoms. This step is generally referred to as pre-deposition. The surface of the silicon wafer is covered with a layer of masking material such as silicon dioxide with a pattern cut into it to expose pre-defined areas of the underlying silicon to the glassy phosphorus-containing material. At the end of the pre-deposition step, a controlled amount of phosphorus atoms are incorporated into the surface of the silicon substrate.

The second step is generally referred to as the drive-in step, at which the silicon wafer, after having the excess glassy material removed from the surface, is subjected to another high temperature excursion. The high temperature diffuses the phosphorus atoms incorporated at the surface of the silicon wafer as a result of the pre-deposition deeper into the bulk of the substrate. At the end of the drive-in step, a region is formed, in the substrate that contains phosphorus atoms. The region usually assumes a cylindrical shape, which reflects the shape of the opening in the silicon dioxide pattern. The boundary of the cylinder where the phosphorus concentration matches the background boron concentration in the substrate is referred to as the metallurgical junction and the distance from the substrate surface to the metallurgical junction is referred to as the depth of the junction.

Boron doped silicon wafers are termed p-type silicon because boron atoms contribute positive charge carriers. Phosphorus atoms are termed n-type dopant because phosphorus atoms contribute negative charge carriers in a silicon device. The junction thus formed is referred to as a n⁺p junction because the concentration of the phosphorus atoms near the substrate surface tends to be much higher than the boron concentration in the bulk of the substrate.

Currently, the two-step deposition-drive-in process is largely replaced by a ion-implantation process where electrically charged dopant ions are injected at accelerated speed into targeted areas at the surface of a semiconductor substrate uncovered by masking materials such as silicon dioxide or photo-resist. The ion-implantation process is favored because it offers better control both in the amount of dopant that is injected into the substrate and the junction depth.

Precise control of both the total dopant and the junction depth is critical for the characteristic of the junctions and hence the performance of the devices that incorporate the junctions. The control is not only a function of the accelerating voltage asserted on the ions but also a function of the species chosen as the dopant. Currently, the n-type dopants commonly used in silicon IC manufacturing are phosphorous and arsenic and the p-type dopant is usually boron.

One engineering challenge of the ion-implantation process is to minimize the effect of channeling—the phenomenon where a small tail of the implanting ions are lodged deeper in the substrate than as desired due to the crystalline characteristic of the target silicon substrate. This extension of implanted tail can be detrimental to the intended function of the p-n junction. For example, in case of MOS transistors with implanted source and drain, channeling narrows the transistor channel length, increases gate-to-drain capacitance. In the case of diodes, it increases the junction current leakage and decrease junction breakdown voltage.

The channeling effect may be ameliorated by disrupting the crystalline structure of the target substrate prior to ion-implantation—a process generally referred to in the art of IC engineering as “pre-amorphization”. One example of a pre-amorphization process is disclosed in the U.S. Pat. application Ser. No. 10/393,749, herein incorporated by reference.

The channeling effect is more pronounced in forming p⁺n junctions with boron as the implanted species because boron is a relatively light element compared to silicon and consequently more easily travels in the “channels” of the host silicon substrate. But as the demand for shallower n⁺p junctions increases as well, arsenic and phosphorus are increasing becoming unsatisfactory even with the aid of de-channeling.

### SUMMARY OF THE INVENTION

The following presents a simplified summary in order to provide a basic understanding of the invention as a prelude to the more detailed description in the later sections. The summary is not intended to identify key or critical elements of the invention, or to delineate its scope.

The present invention eliminates or substantially reduces the problem in forming shallow and abrupt n⁺p junctions, particularly for applications that require sub-0.1 micrometer transistors. The present invention utilizes relatively heavy ions to disrupt the host crystalline lattice at the regions of a semiconductor substrate where the n⁺p junctions are to be formed, followed by implanting the dominant n-type dopant. The damaged lattice is subsequently repaired by subjecting the substrate to a high-temperature anneal process. When the dominant dopant is antimony rather than the commonly used arsenic, the anneal temperature may be substantially lower.

In one embodiment of the invention, an ultra shallow n-type medium-doped region less than 0.015 μm deep in a silicon substrate is constructed by implanting germanium ions into a region such as the drain region of a n-type MOS transistor followed by an implanting antimony ions. The purpose of the germanium implant is to pre-amorphize and thus de-channels the silicon crystalline structure. Following this process, the wafer is heated by a single intermediate-temperature spike anneal to form solid phase epitaxy and to activate the antimony ions. The germanium atoms do not contribute in the current carrying during the operation of the transistor because the germanium is an element in column IV of the periodic table, same as silicon.

In another embodiment, an ultra shallow n-type medium-doped region such as the drain region of an n-type MOS transistor in a silicon substrate is constructed by a low-dose and low energy arsenic ions implant followed by an antimony ion-implant. The arsenic implant de-channels the silicon substrate for the subsequent antimony ion implant. Following the ion-implants, the silicon wafer is annealed at an elevated temperature for ion-activation and for diffusing the arsenic ions towards the surface of the wafer. In this embodiment, the arsenic atoms not only pre-amorphize the silicon substrate prior to the antimony implant, they also supplement the antimony atoms during the operation of the transistor because arsenic and antimony are both column V elements and, when properly incorporated in the silicon lattice, contribute current carrying electrons.

With Ge and As de-channeling the silicon substrate, antimony ion-implant forms superior n⁺p junctions that maintain both superior sheet resistance in the implanted region and abrupt metallurgical junctions with minimum implant tailing. Other heavy elements may also be used as pre-amorphizing agent.

### BRIEF DESCRIPTION OF THE DRAWINGS

FIGS. 1-5 depict the cross-sectional views of a NMOS transistor partially fabricated with a process embodying this invention. For clarity, other structure elements of the transistor such as the source and drain regions are not shown in the figures.

FIG. 6 depicts a typical antimony ion profile in the source and drain regions following the process of the embodiment depicts in FIGS. 1-5.

FIG. 7 depicts typical antimony and arsenic ion profiles in a silicon wafer following another process embodying this invention.

### DETAILED DESCRIPTION OF SPECIFIC EMBODIMENTS

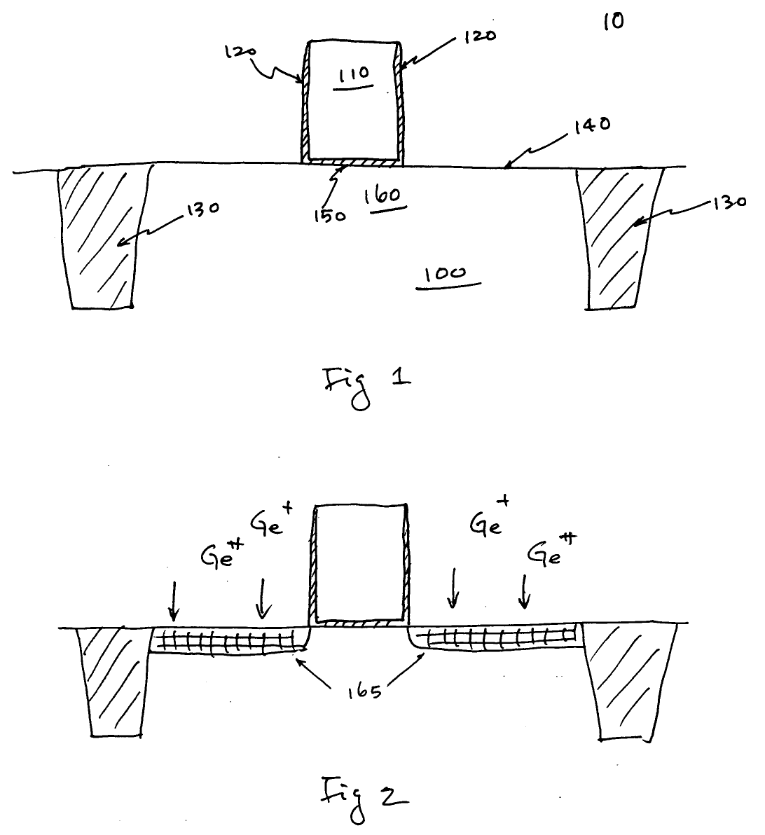

FIG. 1 depicts a partially process NMOS transistor 10, at the surface of a silicon substrate 100, fabricated with a process that embodies this invention. The silicon substrate may be single crystalline or it may be a layer of silicon material disposed over a layer of dielectric material such as silicon dioxide, generally referred to as silicon-on-isolator (SOI). The transistor is isolated from other circuit components (not shown) at this stage of fabrication by a shallow trench region 130 at its periphery and the area of the silicon substrate near the surface 140 is referred to as the active region 160. The shallow trench region 130 is filled with dielectric material such as silicon dioxide. Other dielectric materials such as silicon nitride may also serve as fillers.

At this stage of fabrication, the silicon substrate has gone through many prior process in which a gate electrode 110 is disposed on the substrate, separated from the substrate surface 140 by a layer of dielectric material such as silicon dioxide, generally referred to as the gate oxide 150. Poly-crystalline silicon may be used to form the gate electrode. Other conductive material may also be used to form the gate electrode. The gate oxide may also incorporate other material such as nitrogen atoms to increase it permittivity. Other dielectric material such as silicon nitride, tantalum oxide, zirconium oxide may also be used to isolate the gate electrode 110 from the surface of the substrate 100.

The edges of the gate electrode 110 are covered with what is generally referred to as sidewall spacers 120. Sidewall spacers serve the purpose of masking a portion of the active area 160 during the source and drain implant step as will be discussed in a later paragraph. The sidewall spacers are formed with material that is different from the gate electrode, at least in respect to its response to the an-isotropic etching process. The formation of sidewall spacers are well known in the art of IC fabrication.

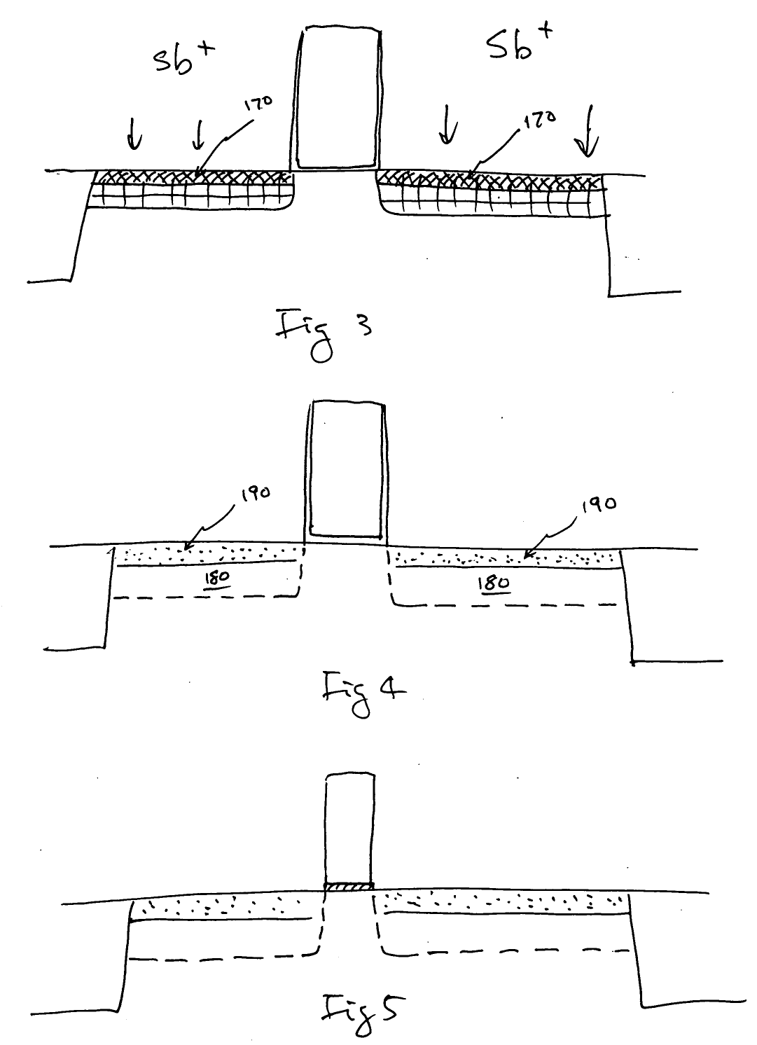

FIG. 2 depicts the transistor 10 at a later process step. At this step, germanium ions are injected into the active area uncovered by the gate electrode 110 and the sidewall spacers 120. In this embodiment, we chose an implant-energy of about 15 keV and a dose of about 1E14 ions/cm². The surface of the active region was kept free of silicon dioxide during the implanting process except possibly a thin layer of native oxide. Other dosages and implant energies may also be used depending on the specific design of the transistor.

This implant converts a thin crystalline layer of the active region 160 near the surface 140 on both sides of the gate electrode into an amorphous layer 165, effectively disrupted the “channels” formed by the orderly crystal lattice in this region.

FIG. 3 depicts the transistor 10 at a later process step. At this step, antimony ions are injected into the previously “de-channeled” region 165. In this embodiment, we chose an implant-energy of about 5 keV and a dose of about 3E14 ions/cm². During the antimony implant, the surface of the active region was again kept free of silicon dioxide except possibly a thin layer of native oxide. Other dosages and implant energies may also be used depending on the specific design of the transistor. Because the region of antimony implant has been sufficiently de-channeled during the previous germanium implant, the antimony ions are well confined to a shallow region 170 near the surface of the silicon substrate.

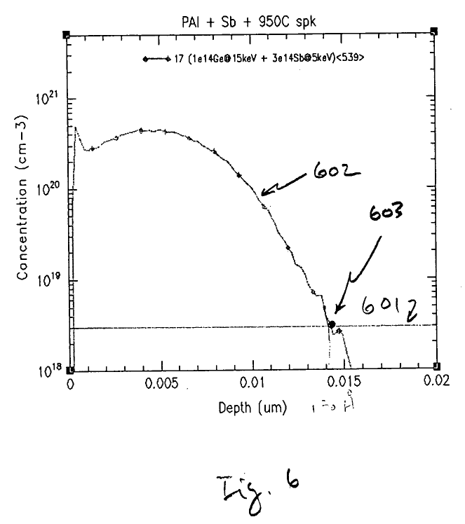

FIG. 4 depicts the transistor 10 at a later process step. At this step, the silicon substrate undergoes a high-temperature treatment. In this embodiment, we chose a 950° C. spike anneal process, which is well-known in the art of IC fabrication. Other high-temperature processes may also be used depending on the specific design of the transistor.

The anneal process repairs the damage to the lattice structure by the energetic ions and converts the amorphized regions 160 and 170 back to a crystalline state and incorporates the implanted antimony ions into the host crystal lattice. The conversion is referred to in the art of IC fabrication as solid phase epitaxy process (SPE) and the incorporation of the dopant ions is referred to as dopant activation. Once activated, the antimony ions contribute to the current conduction in the source and drain regions. The implant dosage and the degree of activation determine the conductivity of the source and drain regions. In the art of IC engineering, the conductivity is expressed in sheet conductance in terms of ohms/square. In FIG. 4, the regions 180 are the implanted region after re-crystallization and regions 190 are the source and the drain region of the transistor 10.

One aspect of this invention over the currently known art is the lowering of the anneal temperature. Comparing to the common practice of forming riMOS source and drain with arsenic as the primary dopant, because arsenic ions require about 1000-1100° C. anneal to activate, we can effectively lower the anneal temperature by about 100° C. Lowering the anneal temperature conserves total thermal budget of the IC fabricating process and is highly desirable.

FIG. 5 depicts the transistor 10 at a later process step. At this step, the sidewall spacers are removed from the transistor structure—usually with a wet chemical process. If the sidewall spacers are made of silicon dioxide, a solution containing hydrofluoric acid is commonly used for this purpose. In this embodiment, the sidewall spacers are removed at this point of the process to prepare the silicon substrate for further processes such as the formation of the source and drain.

Other embodiments of this invention may have the source and drain formed prior to the process steps depicted in FIGS. 1-5.

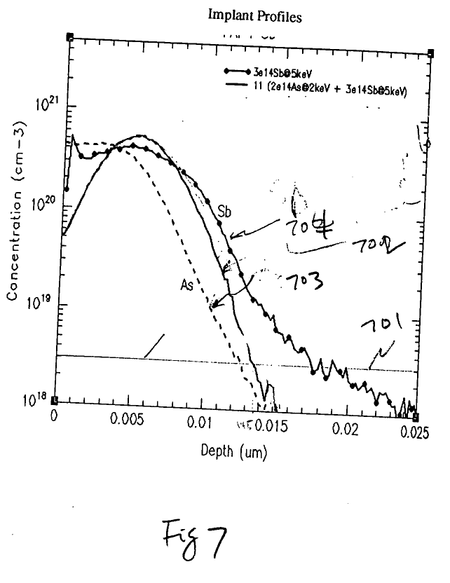

FIG. 6 depicts a typical antimony concentration profile 602 near the surface of the silicon substrate following the germanium and antimony implant and the 950° C. spike anneal processes described in the previous paragraphs. In this embodiment, we chose a silicon substrate previous doped with boron to a concentration of about 3E18 ions/cm³. The boron may be incorporated in the silicon when the silicon wafer was first grown from a melt or it may be incorporated during prior processes such as epitaxial growth or ion-implantation. The metallurgical junction is at about 14.2 nanometers from the substrate surface as depicted by the intersection of the antimony profile curve 602 and the boron profile line 601.

FIG. 7 depicts the results of another embodiment of this invention. In this embodiment, arsenic ions are used to pre-amorphize the active region prior to the antimony ion-implant. The silicon substrate chosen for this embodiment was also previous doped with boron to a concentration of about 3E18 ions/cm³. Curve 703 depicts the concentration profile of arsenic ions implanted at about 2 keV. The dose of arsenic ions is about 2E14 ions/cm². Curve 702 depicts the concentration profile of antimony ions implanted at about 5 keV following the arsenic implant. The dose of antimony ions is about 3E14 ions/cm². The antimony junction is at about 14.5 nanometers from the surface of the silicon substrate and is depicted in FIG. 7 at the intersection of the antimony profile curve 702 and the background boron profile line 701.

Please note that also depicted in FIG. 7 is another typical antimony concentration profile 704 near the surface of a silicon substrate. The antimony implant conditions that generated curve 704 and curve 702 are substantially identical—5 keV and 3E14 ions/cm². While the silicon substrate of curve 702 was pre-amorphized with arsenic ions, the substrate of curve 704 did not undertake a pre-amorphization process. Without pre-amorphization, the channel effect of the antimony ions is clearly show—the junction depth was pushed out to about 19 nanometers, about 4.5 nanometers deeper than as depicted in curve 702.

Please also note that in this embodiment, the arsenic profile curve 703 crosses the boron profile line 701 at a slightly shallower point from the substrate surface than the antimony profile curve 702 does.

Although the exemplary embodiments disclosed in this section describe various aspects of this invention, it will be obvious to the skilled artisans reading this disclosure that equivalent alterations and modification exist. For example, we choose silicon substrate in the embodiments but this invention applies equally well to other host semiconductor materials. Furthermore, the choice of the amorphizing species depends on the choice of the host material and the choice of implant dosage and energy depend on the specific design of the IC components. Factors that influence such decision include, for example, the size of the transistor and its current carrying capability and operating voltage. All such alternations are contemplated as falling within the scope of the present invention.

What is claimed is

1. A method of making a semiconductor device, comprising:
a. providing a silicon substrate having a crystalline p-type surface region, the p-type region having a boron concentration of about 3E19 ions/cm³ ;
b. forming a layer of silicon dioxide over the surface region;
c. forming a polysilicon gate electrode having sidewalls over a portion of the silicon dioxide layer, thereby defining a source region and a drain region in the surface region with a channel region therebetween, the source region having a surface and the drain region having a surface;
d. forming sidewall spacers adjacent the sidewalls;
e. removing the silicon dioxide layer from the surface of the source region and the drain region;
f. implanting a first species of ions into the silicon-dioxide-free surfaces of the source region and the drain region and converting the crystalline surface region into a amorphous region;
g. implanting about 3E14 ions/cm² antimony ions into the amorphized regions at about 5 keV;
h. annealing the silicon substrate at about 950° C. and substantially converting the amorphous region into a re-crystallized region; and
i. removing the sidewall spacers from the sidewalls after the annealing.

2. The method of claim 1 wherein the first species is germanium and the implant dosage is about 1E14 ions/cm² and the implant energy is about 15 keV.

3. The method of claim 1 wherein the first species is arsenic and the implant dosage is about 2E14 ions/cm² and the implant energy is about 2 keV.

4. A method of making a semiconductor device, comprising:
a. providing a semiconductor substrate having a p-type crystalline surface region, the p-type region surface region having a structure including lattice of semiconducting material;
b. forming a layer of dielectric material over the surface region;
c. removing a portion of the dielectric material and uncovering a portion of the underlying p-type crystalline surface region;
d. implanting a first species of ions into the dielectric-material-free surfaces of the uncovered surface region and converting the crystalline surface region into a amorphous region;
e. implanting antimony ions into the amorphized regions; and
f. annealing the silicon substrate at an elevated temperature and substantially converting the amorphous region into a re-crystallized region.

5. The method of claim 4 wherein the semiconductor material includes silicon.

6. The semiconductor device of claim 4 wherein the semiconductor material includes germanium.

7. The method of claim 4 wherein the first species of ions include germanium ions.

8. The method of claim 4 wherein the first species of ions include arsenic ions.

9. The method of claim 5 wherein the first species of ions include elements having atomic weight greater than the atomic weight of arsenic.

10. The method of claim 4 wherein the semiconductor device includes a nMOS transistor and the wherein the uncovered surface region includes a source region and a drain region.

11. The method of claim 4 wherein the semiconductor device includes a n⁺p diode.

12. A semiconductor device, comprising a nMOS transistor having a source region and a drain region including an antimony to boron n⁺p junction with a junction depth of about 15 nanometers, the junction having a substantially reduced antimony implant tail.

13. The semiconductor device of claim 12 further comprising germanium in the source and drain region.

14. The semiconductor device of claim 12 further comprising arsenic in the source and drain region
